(19) United States
(12) Patent Application Publication
(10) Pub. No.: US 2024/0204038 A1
(43) Pub. Date: Jun. 20, 2024

(54) DISPLAY DEVICE AND METHOD FOR MANUFACTURING THE SAME

(71) Applicant: Samsung Display Co., LTD., Yongin-si (KR)

(72) Inventors: Dong Hyun KIM, Yongin-si (KR); Si Jin KIM, Yongin-si (KR)

(73) Assignee: Samsung Display Co., LTD., Yongin-si (KR)

(21) Appl. No.: 18/507,298

(22) Filed: Nov. 13, 2023

(30) Foreign Application Priority Data
Dec. 20, 2022 (KR) 10-2022-0179711

(51) Int. Cl. H01L 27/15

(52) U.S. Cl. CPC H01L 27/156

(57) ABSTRACT

A display device includes a pixel circuit layer including a transistor, a growth substrate disposed on the pixel circuit layer, a light emitting element disposed on the growth substrate, and an electrode disposed on the light emitting element and electrically connecting the light emitting element and the transistor.

### CROSS REFERENCE TO RELATED APPLICATION(S)

This application claims priority to and the benefits of Korean Patent Application No. 10-2022-0179711 under 35 U.S.C. § 119, filed on Dec. 20, 2022, in the Korean Intellectual Property Office (KIPO), the entire contents of which are incorporated herein by reference.

### BACKGROUND

### 1. Technical Field

The disclosure relates to a display device and a method for manufacturing the same.

### 2. Description of the Related Art

As an interest in information display increases and a demand for using portable information media increases, a demand for and commercialization of display devices are focused.

### SUMMARY

An object of the disclosure is to provide a display device with improved yield and a method for manufacturing the same.

In order to achieve the object of the disclosure, a display device according to embodiments of the disclosure may include a pixel circuit layer including a transistor; a growth substrate disposed on the pixel circuit layer; a light emitting element disposed on the growth substrate; and an electrode disposed on the light emitting element and electrically connecting the light emitting element and the transistor.

The growth substrate may be a base layer for epitaxial growth of the light emitting element. The growth substrate may be a sapphire substrate.

The light emitting element may be an inorganic light emitting element. The light emitting element may include a first semiconductor layer disposed on the growth substrate; a light emitting layer disposed on the first semiconductor layer; a second semiconductor layer disposed on the light emitting layer; an electrode layer disposed on the second semiconductor layer; and an insulating layer disposed on the electrode layer, covering the light emitting layer and the second semiconductor layer, and partially exposing the electrode layer. The electrode may electrically connect the electrode layer and the transistor.

The display device may further include sub-pixels each including the light emitting element. The growth substrate may be provided in an island shape in each of the sub-pixels.

The growth substrate may be disposed on an entire area of the pixel circuit layer.

The first semiconductor layer, the light emitting layer, the second semiconductor layer, and the electrode layer may be sequentially stacked on an upper surface of the growth substrate in a direction inclined with respect to the upper surface of the growth substrate. Lower surfaces of the first semiconductor layer, the light emitting layer, the second semiconductor layer, and the electrode layer may be positioned on a same plane.

Each of the first semiconductor layer, the light emitting layer, the second semiconductor layer, and the electrode layer may partially contact the growth substrate.

The display device may further include a reinforcing layer disposed between the light emitting element and the growth substrate. Each of the light emitting layer, the second semiconductor layer, and the electrode layer may partially contact the reinforcing layer.

The reinforcing layer may include silicon oxide.

The display device may further include a reflective layer disposed between the reinforcing layer and the growth substrate.

At least one of the first semiconductor layer, the light emitting layer, the second semiconductor layer, and the electrode layer may include a curved surface in a cross-sectional view.

The light emitting layer and the second semiconductor layer may be spaced apart from the growth substrate. A portion of the electrode layer may partially contact the growth substrate.

The display device may further include a second insulating layer disposed between the electrode layer and side surfaces of the first semiconductor layer and the light emitting layer in a cross-sectional view.

The first semiconductor layer may have an inclined surface inclined with respect to an upper surface of the growth substrate. Each of the light emitting layer, the second semiconductor layer, and the electrode layer may have a thickness in a direction perpendicular to the inclined surface and may be stacked on the inclined surface.

The display device may further include a reinforcing layer disposed between the light emitting element and the growth substrate; and a reflective layer disposed between the reinforcing layer and the growth substrate. Each of the light emitting layer, the second semiconductor layer, and the electrode layer may partially contact the reinforcing layer.

The display device may further include a color conversion layer disposed on the light emitting element and converting a wavelength of light emitted from the light emitting element.

A method for manufacturing a display device according to embodiments of the disclosure may include forming a growth substrate on a pixel circuit layer including a transistor; sequentially forming a first semiconductor layer, a light emitting layer, and a second semiconductor layer on the growth substrate; forming an electrode layer on the second semiconductor layer; forming an insulating layer covering the light emitting layer and the second semiconductor layer and partially exposing the electrode layer; and forming an electrode electrically connecting the electrode layer and the transistor.

The first semiconductor layer, the light emitting layer, and the second semiconductor layer may be formed through an epitaxial growth technique. The growth substrate may be a sapphire substrate.

The first semiconductor layer, the light emitting layer, and the second semiconductor layer may be formed through a lateral growth technique. The first semiconductor layer may have an inclined surface inclined with respect to an upper surface of the growth substrate. Each of the light emitting layer, the second semiconductor layer, and the electrode layer may have a thickness in a direction perpendicular to the inclined surface.

The method may further include anisotropically etching the first semiconductor layer, the second semiconductor layer, and the electrode layer using a mask before the forming of the insulating layer.

### BRIEF DESCRIPTION OF THE DRAWINGS

The accompanying drawings, which are included to provide a further understanding of the disclosure, and are incorporated in and constitute a part of this specification, illustrate embodiments of the disclosure, and, together with the description, serve to explain principles of the disclosure.

FIG. 1 is a schematic plan view illustrating a display device according to an embodiment.

FIG. 2 is a schematic diagram of an equivalent circuit illustrating a sub-pixel included in the display device of FIG. 1 according to an embodiment.

FIGS. 3, 4, and 5 are schematic cross-sectional views illustrating the sub-pixel of FIG. 2 according to an embodiment.

FIG. 6 is a schematic plan view illustrating a pixel of FIG. 2 according to an embodiment.

FIGS. 7 and 8 are schematic cross-sectional views illustrating the sub-pixel of FIG. 2 according to an embodiment.

FIGS. 9, 10, and 11 are schematic cross-sectional views illustrating the sub-pixel of FIG. 2 according to an embodiment.

FIGS. 12 and 13 are schematic cross-sectional views illustrating the sub-pixel of FIG. 2 according to an embodiment.

FIG. 14 is a schematic cross-sectional view illustrating the sub-pixel of FIG. 2 according to an embodiment.

FIGS. 15 and 16 are schematic diagrams for explaining a method of forming a light emitting element included in the sub-pixel of FIG. 14 according to an embodiment.

FIGS. 17, 18, and 19 are schematic cross-sectional views illustrating a pixel included in the display device of FIG. 1 according to an embodiment.

FIG. 20 is a schematic cross-sectional view illustrating the pixel included in the display device of FIG. 1 according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

As the disclosure allows for various changes and numerous embodiments, particular embodiments will be illustrated in the drawings and described in detail in the written description. However, this is not intended to limit the disclosure to particular modes of practice, and it is to be appreciated that all changes, equivalents, and substitutes that do not depart from the spirit and technical scope of the disclosure are encompassed in the disclosure.

It will be understood that, although the terms “first”. “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element. In the disclosure, the singular expressions are intended to include the plural expressions as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” It is also noted that, as used herein, the terms “substantially.” “about,” and other similar terms, are used as terms of approximation and not as terms of degree, and, as such, are utilized to account for inherent deviations in measured, calculated, and/or provided values that would be recognized by one of ordinary skill in the art.

It will be further understood that the terms “comprise”, “include”, “have”, etc. used in the disclosure, specify the presence of stated features, integers, steps, operations, elements, components, or combinations of them but do not preclude the presence or addition of one or more other features, integers, steps, operations, elements, components, or combinations thereof. In addition, when a first part such as a layer, film, region, part, etc. is “on” a second part, the first part may be not only “directly on” the second part but a third part may intervene between them. Furthermore, in the disclosure, when a first part such as a layer, film, region, part, etc. is formed on a second part, a direction in which the first part is formed is not limited to an upper direction of the second part, but may include a side or a lower direction of the second part. To the contrary, when a first part such as a layer, film, region, part, etc. is “under” a second part, the first part may be not only “directly under” the second part but a third part may intervene between them.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only. Z only, or any combination of two or more of X, Y, and Z, such as, for instance, XYZ, XYY. YZ, and ZZ.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Advantages and features of the disclosure and methods of achieving them will become apparent with reference to the embodiments described below in detail in conjunction with the accompanying drawings. However, the disclosure is not limited to the embodiments disclosed below and may be implemented in various different forms. In the following description, when a first part is connected to a second part, this includes not only the case where the first part is directly connected to the second part, but also the case where a third part is interposed therebetween and they are electrically connected to each other. In embodiments of the disclosure, “connection” between two components may mean to encompass both an electrical connection and a physical connection.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display device according to embodiments of the disclosure will be described with reference to drawings related to embodiments of the disclosure.

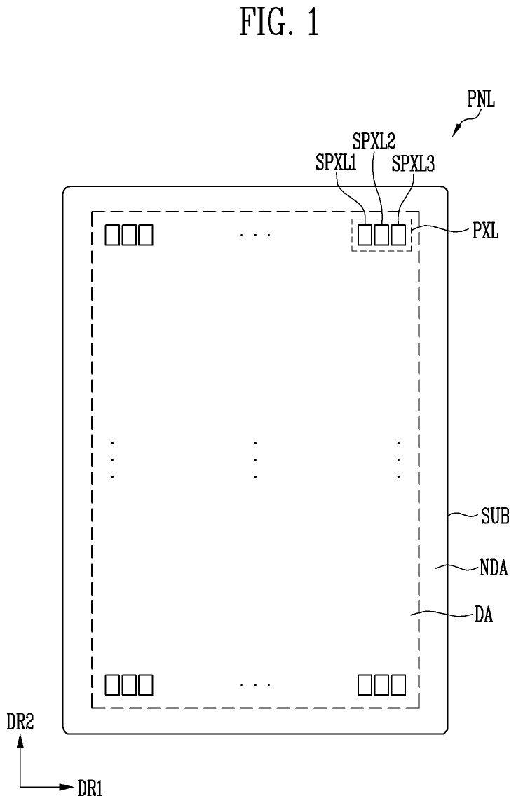

FIG. 1 is a schematic plan view illustrating a display device according to an embodiment. FIG. 1 shows a display device as an embodiment of an electronic device, in particular, a display panel PNL included in the display device.

For convenience of description, FIG. 1 schematically shows a structure of the display panel PNL centered on a display area DA. However, according to embodiments, at least one driver circuit part (for example, at least one of a scan driver and a data driver), wirings, and/or pads not shown may be further disposed on the display panel PNL.

In case that the display device is an electronic device having a display surface applied to at least one surface, such as a smart phone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, and a wearable device, the disclosure can be applied.

Referring to FIG. 1, the display panel PNL may include a substrate SUB and a pixel PXL disposed on the substrate SUB.

The substrate SUB may be a base member of the display panel PNL and may be a rigid or flexible substrate, film, or the like. For example, the substrate SUB may be a rigid substrate made of glass, tempered glass, or the like, a flexible substrate (or thin film) made of plastic, metal, or the like, or at least one insulating layer. The material and/or physical properties of the substrate SUB are not particularly limited. The substrate SUB may be transparent or opaque. According to an embodiment, the substrate SUB may include a reflective material.

The display panel PNL and the substrate SUB for forming the display panel PNL may include the display area DA for displaying an image and a non-display area NDA other than the display area DA.

The pixel PXL may be disposed in the display area DA. Various wirings, pads, and/or embedded circuit parts connected to the pixel PXL of the display area DA may be disposed in the non-display area NDA.

The pixel PXL may include sub-pixels SPXL1 to SPXL3. For example, the pixel PXL may include a first sub-pixel SPXL1, a second sub-pixel SPXL2, and third sub-pixels SPXL3.

Each of the sub-pixels SPXL1 to SPXL3 may emit light of a color (e.g., a predetermined or selectable color). According to an embodiment, the sub-pixels SPXL1 to SPXL3 may emit light of different colors. For example, the first sub-pixel SPXL1 may emit light of a first color, the second sub-pixel SPXL2 may emit light of a second color, and the third sub-pixel SPXL3 may emit light of a third color. For example, the first sub-pixel SPXL1 may be a red pixel emitting red light, the second sub-pixel SPXL2 may be a green pixel emitting green light, and the third sub-pixel SPXL3 may be a blue pixel emitting blue light, but the disclosure is not limited thereto.

In an embodiment, each of the first sub-pixel SPXL1, the second sub-pixel SPXL2, and the third sub-pixel SPXL3 may include a first color light emitting element, a second color light emitting element, and a third color light emitting element as light sources and may emit light of the first color, the second color, and the third color, respectively. In another embodiment, the first sub-pixel SPXL1, the second sub-pixel SPXL2, and the third sub-pixel SPXL3 may include light emitting elements emitting light of a same color, and may emit light of the first color, the second color, and the third color, respectively, by including color conversion layers and/or color filters of different colors disposed on each light emitting element. However, color, type, and/or number of the sub-pixels SPXL1 to SPXL3 constituting each pixel PXL are not particularly limited. For example, a color of light emitted from each pixel PXL may be variously changed.

The sub-pixels SPXL1 to SPXL3 may be regularly arranged according to an arrangement structure such as a stripe, a PENTILE™, or the like. For example, referring to FIG. 1, the first, second, and third sub-pixels SPXL1, SPXL2, and SPXL3 may be sequentially and repeatedly arranged in a first direction DR1, and may also be repeatedly arranged in a second direction DR2 intersecting the first direction DR1. The first, second, and third sub-pixels SPXL1, SPXL2, and SPXL3 disposed adjacent to each other may constitute one pixel PXL emitting light of various colors. However, an arrangement structure of the sub-pixels SPXL1 to SPXL3 is not limited thereto, and the sub-pixels SPXL1 to SPXL3 may be arranged in the display area DA in various structures and/or methods.

In an embodiment, each of the sub-pixels SPXL1 to SPXL3 may be configured as an active pixel. For example, each of the sub-pixels SPXL1 to SPXL3 may include at least one light source (for example, a light emitting element) driven by a control signal (e.g., a predetermined or selectable control signal, for example, a scan signal or a data signal) and/or a power source (e.g., a predetermined or selectable power source, for example, a first power source or a second power source). However, type, structure, and/or driving method of the sub-pixels SPXL1 to SPXL3 applicable to the display device is not particularly limited.

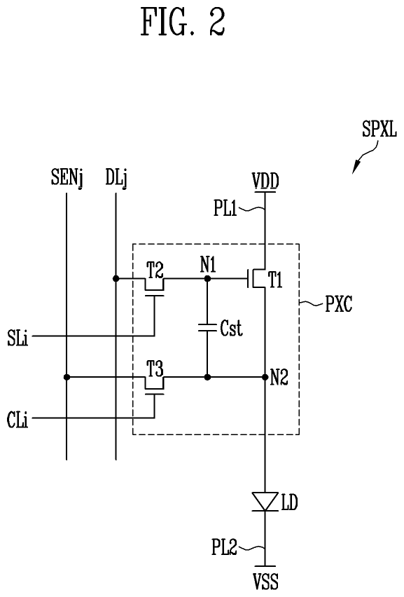

FIG. 2 is a schematic diagram of an equivalent circuit illustrating a sub-pixel included in the display device of FIG. 1 according to an embodiment.

In the following embodiments, when referring to the first sub-pixel SPXL1, the second sub-pixel SPXL2, and the third sub-pixel SPXL3 collectively, the first sub-pixel SPXL1, the second sub-pixel SPXL2, and/or the third sub-pixel SPXL3 may be referred to as “sub-pixel SPXL” or “sub-pixels SPXL”. FIG. 2 shows an electrical connection relationship of components included in a sub-pixel SPXL applicable to an active matrix display device according to embodiments. However, the connection relationship of the components of the sub-pixel SPXL is not limited thereto.

Referring to FIGS. 1 and 2, the sub-pixel SPXL may include a light emitting element LD generating light having a luminance corresponding to a data signal. The sub-pixel SPXL may further include a pixel circuit PXC for driving the light emitting element LD.

The light emitting element LD may be electrically connected between a first power source line PL1 and a second power source line PL2. An anode electrode of the light emitting element LD may be electrically connected to the first power source line PL1, and a cathode electrode of the light emitting element LD may be electrically connected to the second power source line PL2. The first power source line PL1 may be connected to a first driving power source VDD to receive a voltage of the first driving power source VDD, and the second power source line PL2 may be connected to a second driving power source VSS to receive a voltage of the second driving power source VSS. The first driving power source VDD and the second driving power source VSS may have different potentials. For example, the first driving power source VDD may be a high-potential power source, and the second driving power source VSS may be a low-potential power source. A potential difference between the first and second driving power sources VDD and VSS may be set to be higher than or equal to a threshold voltage of the light emitting element LD during an emission period of each sub-pixel SPXL.

The light emitting element LD may emit light with a luminance corresponding to a driving current supplied from the pixel circuit PXC. For example, the pixel circuit PXC may supply a driving current corresponding to a grayscale value of corresponding frame data of the pixel circuit PXC to the light emitting element LD during each frame period.

The pixel circuit PXC may be connected to a scan line SLi and a data line DLj. Also, the pixel circuit PXC may be connected to a control line CLi and a sensing line SENj. For example, in case that the sub-pixel SPXL is disposed in an i-th row and a j-th column in the display area DA, the pixel circuit PXC of the sub-pixel SPXL may be connected to an i-th scan line SLi, a j-th data line DLj, an i-th control line CLi, and a j-th sensing line SENj in the display area DA.

In an embodiment, the pixel circuit PXC may include transistors T1 to T3 and a storage capacitor Cst. For example, the pixel circuit PXC may include a first transistor T1, a second transistor T2, a third transistor T3, and the storage capacitor Cst.

The first transistor T1 may be a driving transistor for controlling the drive current applied to the light emitting element LD, and may be connected between the first driving power source VDD and the light emitting element LD. A first terminal (first electrode or first transistor electrode) of the first transistor T1 may be electrically connected to the first driving power source VDD through the first power source line PL1, and a second terminal (second electrode or second transistor electrode) of the first transistor T1 may be electrically connected to a second node N2. A gate electrode of the first transistor T1 may be electrically connected to a first node N1. The first transistor T1 may control an amount of driving current applied from the first driving power source VDD to the light emitting element LD through the second node N2 according to a voltage applied to the first node N1. In an embodiment, the first terminal of the first transistor T1 may be a drain electrode, and the second terminal of the first transistor T1 may be a source electrode, but the disclosure is not limited thereto. According to an embodiment, the first terminal may be a source electrode and the second terminal may be a drain electrode.

The second transistor T2 may be a switching transistor that selects the sub-pixel SPXL and activates the sub-pixel SPXL in response to a scan signal, and may be connected between the data line DLj and the first node N1. A first terminal of the second transistor T2 may be connected to the data line DLj, a second terminal of the second transistor T2 may be connected to the first node N1, and a gate electrode of the second transistor T2 may be connected to the scan line SLi. The first terminal and the second terminal of the second transistor T2 may be different terminals. For example, in case that the first terminal is a drain electrode, the second terminal may be a source electrode.

The second transistor T2 may be turned on in case that the scan signal of a gate-on voltage (for example, a high-level voltage) is supplied from the scan line SLi to electrically connect the data line DLj and the first node N1. The first node N1 may be a point where the second terminal of the second transistor T2 and the gate electrode of the first transistor T1 are connected to each other, and the second transistor T2 may transfer the data signal to the gate electrode of the first transistor T1.

The third transistor T3 may be an initialization transistor initializing the second node N2 and may be connected between the sensing line SENj and the second node N2. A second terminal of the third transistor T3 may be connected to the second terminal of the first transistor T1, a first terminal of the third transistor T3 may be connected to the sensing line SENj, and a gate electrode of the third transistor T3 may be connected to the control line CLi.

The third transistor T3 may be turned on in case that a sensing control signal of a gate-on voltage is supplied from the control line CLi to electrically connect the sensing line SENj and the second node N2. In case that the scan signal of the gate-on voltage (for example, the high-level voltage) is supplied from the control line CLi, the sensing line SENj and the second node N2 may be electrically connected.

In case that a voltage of the initialization power source is applied to the sensing line SENj, the third transistor T3 may transfer the voltage of the initialization power source to the second node N2. Accordingly, a second storage electrode of the storage capacitor Cst electrically connected to the second node N2 may be initialized.

According to an embodiment, the third transistor T3 may connect the first transistor T1 to the sensing line SENj, and a sensing signal may be obtained through the sensing line SENj. Characteristics of the sub-pixel SPXL including a threshold voltage of the first transistor T1 may be detected using the sensing signal. Information on the characteristics of the sub-pixel SPXL may be used to convert image data in order to compensate for a deviation in characteristics between sub-pixels SPXL.

The storage capacitor Cst may be formed or electrically connected between the first node N1 and the second node N2. The storage capacitor Cst may be charged with a data voltage corresponding to the data signal supplied to the first node N1 during a frame period. The storage capacitor Cst may store a voltage corresponding to a difference between a voltage of the gate electrode of the first transistor T1 and a voltage of the second node N2.

In FIG. 2, although all of the transistors T1 to T3 included in the pixel circuit PXC are shown as n-type transistors, the disclosure is not necessarily limited thereto. For example, at least one of the transistors T1 to T3 may be changed to a p-type transistor.

A structure and driving method of the sub-pixel SPXL may be variously changed. For example, the pixel circuit PXC may be composed of pixel circuits having various structures and/or driving methods other than the embodiment shown in FIG. 2.

For example, the pixel circuit PXC may not include the third transistor T3. For example, the pixel circuit PXC may include other circuit elements such as a compensation transistor for compensating the threshold voltage of the first transistor T1, an initialization transistor for initializing a voltage of the first node N1, a light emitting control transistor for controlling a period during which the driving current is supplied to the light emitting element LD, a boosting capacitor for boosting the voltage of the first node N1, and/or the like.

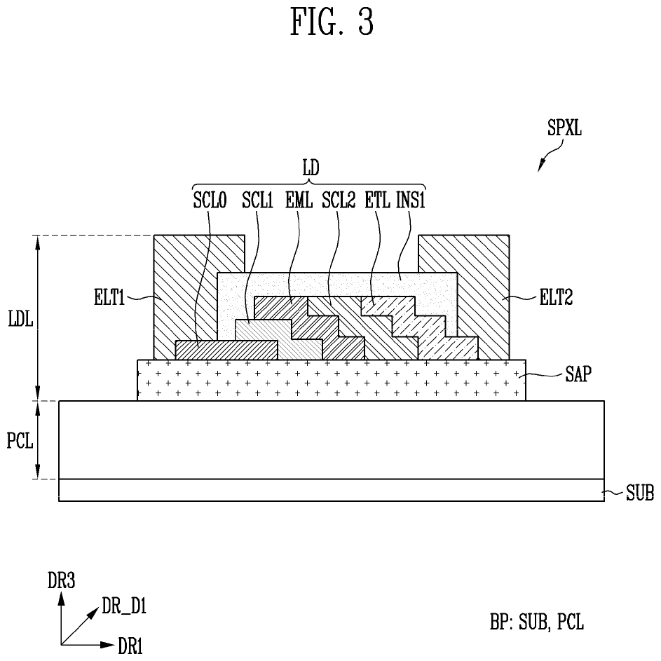

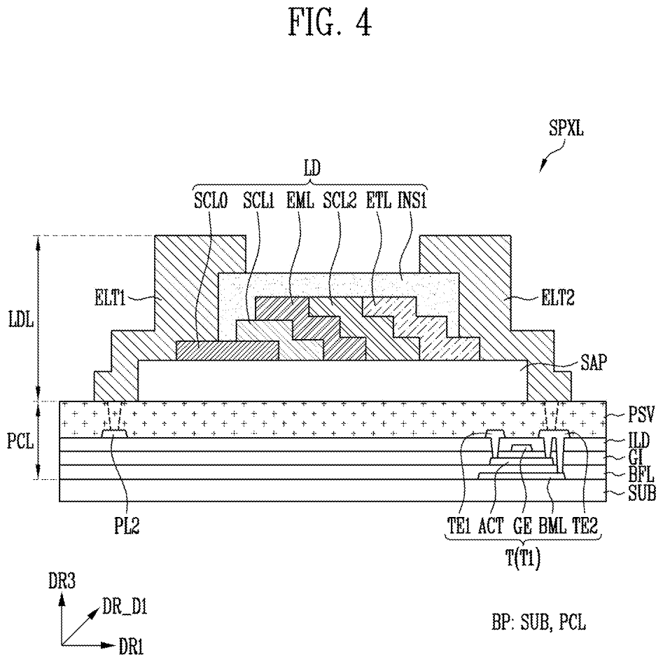

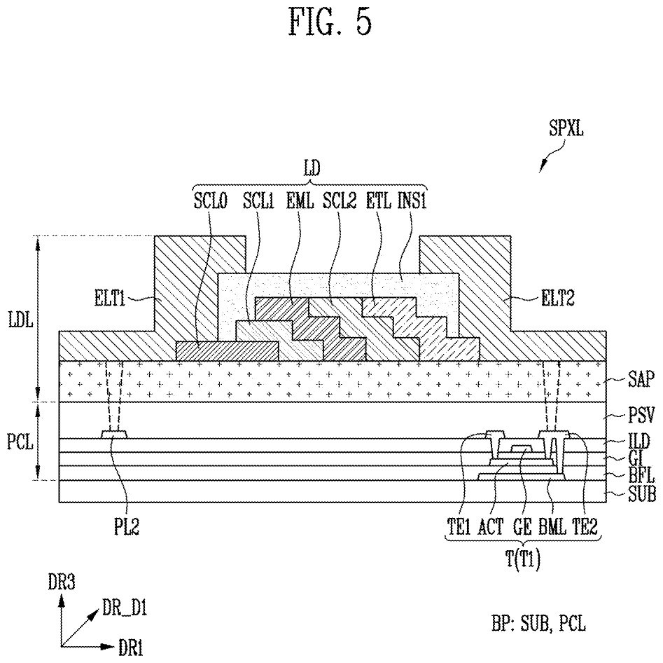

FIGS. 3, 4, and 5 are schematic cross-sectional views illustrating the sub-pixel of FIG. 2 according to an embodiment. FIGS. 4 and 5 show a transistor T (or the first transistor T1 (sec, e.g., FIG. 2)) and the second power source line PL2 (see, e.g., FIG. 2) as embodiments of circuit elements that may be disposed in a pixel circuit layer PCL.

Referring to FIGS. 1 to 5, the sub-pixel SPXL (or the display device) may include the pixel circuit layer PCL and a light emitting element layer LDL disposed on the substrate SUB. The substrate SUB and the pixel circuit layer PCL may be collectively referred to as a lower panel BP.

As shown in FIGS. 4 and 5, the pixel circuit layer PCL may include the first transistor T1, the second power source line PL2, and multiple insulating layers BFL, GI, ILD, and PSV. The first transistor T1 may include a lower metal layer BML, a semiconductor pattern ACT, a gate electrode GE, a first terminal TE1 (the first electrode or the first transistor electrode), and a second terminal TE2 (the second electrode or the second transistor electrode).

The lower metal layer BML (or a first conductive layer) may be disposed between the substrate SUB and a buffer layer BFL. The lower metal layer BML may include a conductive material. The conductive material may include at least one of silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), the like, and an alloy thereof. The lower metal layer BML may be formed of a single layer, a double layer, or a multilayer. The lower metal layer BML and the gate electrode GE of the first transistor T1 may overlap each other with the buffer layer BFL interposed between the lower metal layer BML and the gate electrode GE of the first transistor T1 in a third direction DR3. The third direction DR3 may intersect the first and second direction DR1 and DR2. The lower metal layer BML may be disposed below the semiconductor pattern ACT of the first transistor T1. The lower metal layer BML may serve as a light-blocking pattern to stabilize operating characteristics of the first transistor T1. Also, the lower metal layer BML may be physically and/or electrically connected to the second terminal TE2 of the first transistor T1 to be described below through a contact hole of the insulating layers (sec, e.g., BFL, GI, and ILD of FIGS. 4 and 5). Accordingly, the threshold voltage of the first transistor T1 may be moved in a negative direction or a positive direction.

According to an embodiment, the first transistor T1 may not include the lower metal layer BML, and the buffer layer BFL may be directly positioned on the substrate SUB.

The buffer layer BFL (or a first pixel circuit layer insulating layer) may be positioned on the substrate SUB and may cover the lower metal layer BML. The buffer layer BFL may prevent impurities from diffusing into the pixel circuit layer PCL. The buffer layer BFL may include an inorganic material. For example, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be omitted depending on a material and process conditions of the substrate SUB, and the like.

The semiconductor pattern ACT may be positioned on the buffer layer BFL. The semiconductor pattern ACT may include a first region (for example, a drain region) connected to the first terminal TE1, a second region (for example, a source region) connected to the second terminal TE2, and a channel region between the first region and the second region. The channel region may overlap the gate electrode GE of the first transistor T1 in the third direction DR3. The semiconductor pattern ACT may be made of polysilicon, amorphous silicon, an oxide semiconductor, the like, or a combination thereof.

A gate insulating layer GI (or a pixel circuit layer second insulating layer) may be disposed on the semiconductor pattern ACT. The gate insulating layer GI may be partially disposed on the semiconductor pattern ACT or entirely disposed on the substrate SUB. The gate insulating layer GI may include an inorganic material. However, the disclosure is not limited thereto, and the gate insulating layer GI may include an organic material. For example, the gate insulating layer GI may include at least one of a polyacrylates resin, an epoxy resin, a phenolic resin, a polyamides resin, a polyimides resin, an unsaturated polyesters resin, a poly-phenylene ethers resin, a poly-phenylene sulfides resin, and a benzocyclobutene resin.

The gate electrode GE (or a second conductive layer) may be disposed on the gate insulating layer GI. The gate electrode GE may overlap the channel region of the semiconductor pattern ACT in the third direction DR3. The gate electrode GE may include a conductive material similarly to the lower metal layer BML.

An interlayer insulating layer ILD (or a third pixel circuit layer insulating layer) may cover the gate electrode GE and may be entirely disposed on the substrate SUB. Similar to the gate insulating layer GI, the interlayer insulating layer ILD may include an inorganic material. The interlayer insulating layer ILD may include an organic material.

A third conductive layer may be disposed on the interlayer insulating layer ILD. The third conductive layer may include a conductive material similarly to the first conductive layer. The third conductive layer may include the first terminal TE1, the second terminal TE2, and the second power source line PL2.

The first terminal TE1 may contact or be connected to the first region of the semiconductor pattern ACT through a contact hole penetrating the interlayer insulating layer ILD. The second terminal TE2 may contact or be connected to the second region of the semiconductor pattern ACT through a contact hole penetrating the interlayer insulating layer ILD, and may also contact or be connected to the lower metal layer BML through a contact hole penetrating the interlayer insulating layer ILD and the buffer layer BFL.

A passivation layer PSV (a via layer or a fourth pixel circuit layer insulating layer) may be entirely disposed on the substrate SUB to cover the third conductive layer. The passivation layer PSV may include an inorganic material and/or an organic material. The passivation layer PSV may be provided as a single layer or as multiple layers including a double layer. In case that the passivation layer PSV includes an organic material, a flat surface may be provided on an upper surface of the passivation layer PSV.

The light emitting element layer LDL may be positioned on the passivation layer PSV (or the pixel circuit layer PCL).

The light emitting element layer LDL (or a display element layer) may include a dedicated substrate SAP, a light emitting element LD, a first electrode ELT1, and a second electrode ELT2.

The dedicated substrate SAP (a growth substrate, an epitaxial substrate, or a base layer) may be directly disposed on the pixel circuit layer PCL (or the passivation layer PSV providing the flat surface).

The dedicated substrate SAP may be a substrate or layer suitable for epitaxial growth (or epitaxy) of a semiconductor (or the light emitting element LD). For example, the dedicated substrate SAP may be a substrate including a material such as silicon (Si), sapphire, SiC, GaN, GaAs, ZnO, the like, or a combination thereof. For example, the dedicated substrate SAP may be a sapphire substrate, a silicon substrate, or the like. The substrate SUB may be a substrate of various types and/or materials. As long as the epitaxial growth for forming the light emitting element LD can be smoothly performed, a type or material of the dedicated substrate SAP is not particularly limited. Process technologies for the epitaxial growth may include metal-organic vapor phase epitaxy (MOVPE), metal-organic chemical vapor deposition (MOCVD), molecular beam epitaxy (MBE), liquid phase epitaxy (LPE), vapor phase epitaxy (VPE), or the like. In order to epitaxially grow (form or stack) the light emitting element LD on the lower panel BP, the dedicated substrate SAP may be provided.

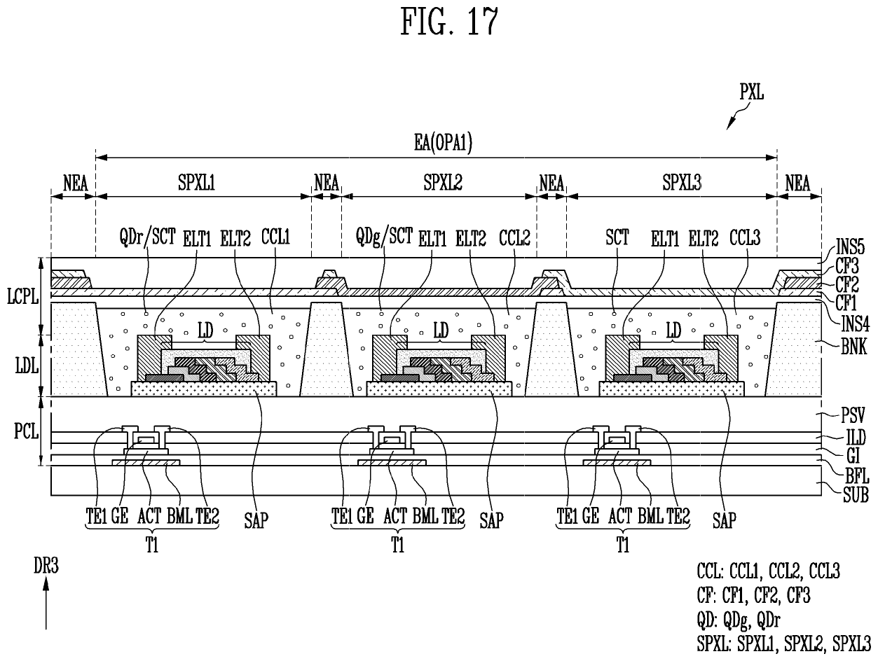

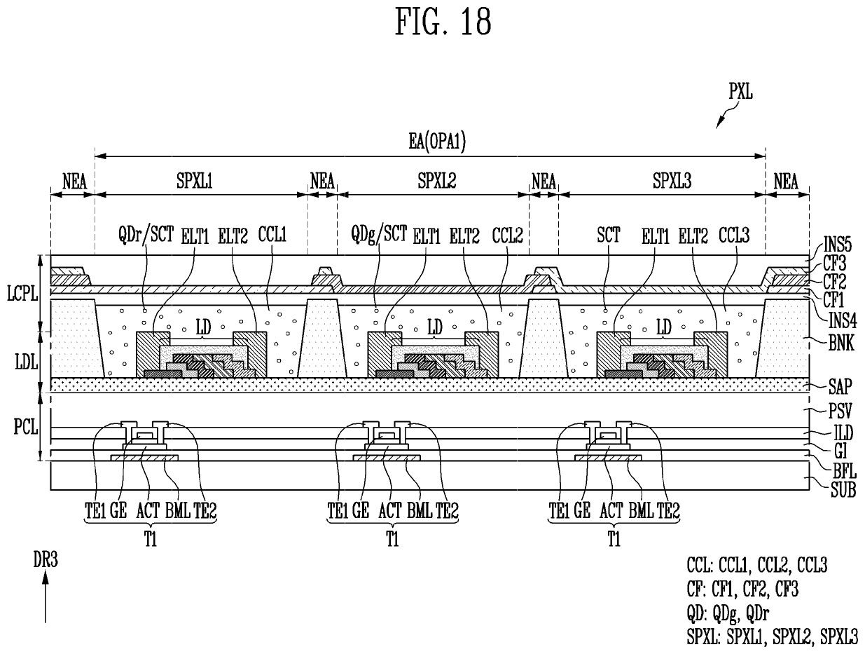

In an embodiment, the dedicated substrate SAP may be independently arranged for each sub-pixel SPXL (or for each light emitting element LD). For example, the dedicated substrate SAP may be separated from or spaced apart from the dedicated substrate SAP of other sub-pixels SPXL, and the dedicated substrate SAP may be arranged in an island shape corresponding to each sub-pixel SPXL (or each light emitting element LD) (see, e.g., FIG. 17). However, the disclosure is not limited thereto, and the dedicated substrate SAP may be disposed on an entire area of the substrate SUB (or the lower panel BP) (see, e.g., FIG. 18).

The light emitting element LD may be disposed on the dedicated substrate SAP, and may include a third semiconductor layer SCL0, a first semiconductor layer SCL1, a light emitting layer EML, a second semiconductor layer SCL2, and an electrode layer ETL. For example, the third semiconductor layer SCL0, the first semiconductor layer SCL1, the light emitting layer EML, the second semiconductor layer SCL2, and the electrode layer ETL stacked on the dedicated substrate SAP may constitute or define the light emitting element LD. The third semiconductor layer SCL0, the first semiconductor layer SCL1, the light emitting layer EML, the second semiconductor layer SCL2, and the electrode layer ETL may be sequentially stacked on the dedicated substrate SAP in a first oblique direction DR_D1 (for example, in an inclined direction on an upper surface of the dedicated substrate SAP). The first oblique direction DR_D1 may intersect the first and third directions DR1 and DR3. The light emitting element LD may further include a first insulating layer INS1.

The third semiconductor layer SCL0 may be disposed on the dedicated substrate SAP. The third semiconductor layer SCL0 may include a nitride-based semiconductor or a phosphide-based semiconductor. For example, the third semiconductor layer SCL0 may include a nitride-based semiconductor including at least one of GaN, AlGaN, InGaN, InAlGaN, AlN, and InN, or a phosphide-based semiconductor including at least one of GaP, InGaP, AlGaP, InAlGaP, AlP, and InP. The third semiconductor layer SCL0 may be an undoped semiconductor layer not doped with an impurity. The third semiconductor layer SCL0 may reduce a lattice constant difference between the dedicated substrate SAP and the first semiconductor layer SCL1.

The first semiconductor layer SCL1 may be disposed on the third semiconductor layer SCL0 and the dedicated substrate SAP. The first semiconductor layer SCL1 may partially overlap the third semiconductor layer SCL0 in the third direction DR3, and a portion of the first semiconductor layer SCL1 may contact the dedicated substrate SAP.

The first semiconductor layer SCL1 may be a first conductivity type semiconductor layer including a first conductivity type dopant. For example, the first semiconductor layer SCL1 may be an n-type semiconductor layer. For example, the first semiconductor layer SCL1 may include at least one semiconductor material selected from GaN, AlGaN, InGaN, InAlGaN, AlN, and InN, and may include an n-type dopant such as Si, Ge, Sn, or the like. However, the material constituting the first semiconductor layer SCL1 is not limited thereto, and the first semiconductor layer SCL1 may be composed of various other materials.

The light emitting layer EML (or an active layer) may be disposed on the first semiconductor layer SCL1 and the dedicated substrate SAP. The light emitting layer EML may partially overlap the first semiconductor layer SCL1 in the third direction DR3, and a portion of the light emitting layer EML may contact the dedicated substrate SAP.

The light emitting layer EML may be formed in a single-quantum well or multi-quantum well structure. In case that a voltage higher than a threshold voltage is applied to ends of the light emitting element LD, light may be emitted while electron-hole pairs recombine in the light emitting layer EML.

In an embodiment, the light emitting layer EML may emit light in a visible light wavelength band, for example, light in a wavelength band in a range of about 400 nm to about 900 nm. For example, the light emitting layer EML may emit blue light having a wavelength in a range of about 450 nm to about 480 nm, green light having a wavelength in a range of about 480 nm to about 560 nm, or red light having a wavelength in a range of about 620 nm to about 750 nm. A color and/or wavelength band of light generated from the light emitting layer EML may be changed.

The light emitting layer EML may include a nitride-based semiconductor or a phosphide-based semiconductor. For example, the light emitting layer EML may include a nitride-based semiconductor including at least one of GaN, AlGaN, InGaN, InGaAlN, AlN, InN, and AlInN, or a phosphide-based semiconductor including at least one of GaP, InGaP. AlGaP. InAlGaP, AlP, and InP. A material constituting the light emitting layer EML is not limited thereto, and various other materials may be used to form the light emitting layer EML.

In an embodiment, the light emitting layer EML may include an element corresponding the color (or wavelength band) of light, and the color of light generated from the light emitting layer EML may be controlled by adjusting a content and/or composition ratio of the element. For example, the light emitting layer EML may be formed of multiple layers having a structure in which GaN layers and InGaN layers are alternately and/or repeatedly stacked each other, and light of a color (e.g., a specific color) may be emitted according to a content and/or composition ratio of indium (In) included in the InGaN layer. Accordingly, the light emitting element LD having a desired color may be manufactured by adjusting the content and/or composition ratio of indium (In) included in the light emitting layer EML.

The second semiconductor layer SCL2 may be disposed on the light emitting layer EML and the dedicated substrate SAP. The second semiconductor layer SCL2 may partially overlap the light emitting layer EML in the third direction DR3, and a portion of the second semiconductor layer SCL2 may contact the dedicated substrate SAP.

The second semiconductor layer SCL2 may include a semiconductor layer, and the first semiconductor layer SCL1 and the second semiconductor layer SCL2 may be different types. The second semiconductor layer SCL2 may be a second conductivity type semiconductor layer including a second conductivity type dopant. For example, the second semiconductor layer SCL2 may include a p-type semiconductor layer. For example, the second semiconductor layer SCL2 may include at least one semiconductor material selected from InAlGaN, GaN, AlGaN, InGaN, AlN, and InN, and may include a p-type dopant such as Mg or the like. However, the material constituting the second semiconductor layer SCL2 is not limited thereto, and the second semiconductor layer SCL2 may be composed of various other materials.

The electrode layer ETL may be disposed on the second semiconductor layer SCL2 and the dedicated substrate SAP. The electrode layer ETL may partially overlap the second semiconductor layer SCL2 in the third direction DR3, and a portion of the electrode layer ETL may contact the dedicated substrate SAP.

The electrode layer ETL may protect the second semiconductor layer SCL2 and constitute an electrode for electrically connecting the second semiconductor layer SCL2 to an electrode (e.g., a predetermined or selectable electrode) (for example, the second electrode ELT2) or wiring. For example, the electrode layer ETL may be an Ohmic contact electrode, a Schottky contact electrode, or the like.

In an embodiment, the electrode layer ETL may include a metal or a metal oxide. For example, the electrode layer ETL may be formed of a metal such as chromium (Cr), titanium (Ti), aluminum (Al), gold (Au), nickel (Ni), copper (Cu), the like, an oxide, or an alloy thereof. The electrode layer ETL may be formed of a transparent conductive material such as indium tin oxide (ITO), indium zinc oxide (IZO), zinc oxide (ZnO), indium gallium zinc oxide (IGZO), the like, or a mixture thereof. A material constituting the electrode layer ETL is not limited thereto, and various other conductive materials may be used to form the electrode layer ETL.

The first insulating layer INS1 (or insulating layer) may be disposed on the third semiconductor layer SCL0, the first semiconductor layer SCL1, the light emitting layer EML, the second semiconductor layer SCL2, and the electrode layer ETL, and may cover the first semiconductor layer SCL1, the light emitting layer EML, and the second semiconductor layer SCL2.

In case that the first insulating layer INS1 is provided on a surface of the light emitting element LD, a defect (or short circuit) of the light emitting element LD may be prevented. Accordingly, electrical stability of the light emitting element LD may be secured. In case that the first insulating layer INS1 is provided on the surface of the light emitting element LD, surface defects of the light emitting element LD may be minimized, thereby improving the lifespan and efficiency of the light emitting element LD.

The first insulating layer INS1 may include a transparent insulating material. Accordingly, light generated by the light emitting layer EML may pass through the first insulating layer INS1 and be emitted to an outside of the light emitting element LD. For example, the first insulating layer INS1 may include at least one insulating material selected from silicon oxide (SiOₓ) (for example, SiO₂), silicon nitride (SiNₓ) (for example, Si₃N₄), aluminum oxide (AlₓO_{y}) (for example, Al₂O₃), titanium oxide (TiₓO_{y}) (for example, TiO₂), and hafnium oxide (HfOₓ), or other insulating material. The first insulating layer INS1 may be composed of a single layer or multiple layers. For example, the first insulating layer INS1 may be formed of a double layer.

The first insulating layer INS1 may partially expose the third semiconductor layer SCL0 and the electrode layer ETL at ends of the light emitting element LD (e.g., an end of the light emitting element LD and another end of the light emitting element LD). For example, the first insulating layer INS1 may not be provided on a portion of the third semiconductor layer SCL0, and the portion of the third semiconductor layer SCL0 may be exposed. Also, the first insulating layer INS1 may not be provided on a portion of the electrode layer ETL, and the portion of the electrode layer ETL may be exposed. Accordingly, the third semiconductor layer SCL0 and the electrode layer ETL may be connected to at least one electrode (for example, the first electrode ELT1 and the second electrode ELT2), wiring, and/or conductive pattern to apply a driving power source and/or a signal to the light emitting element LD.

According to an embodiment, the first insulating layer INS1 may partially expose the first semiconductor layer SCL1, and the first electrode layer ETL1 may be connected to an electrode (for example, the first electrode ELT1).

Since the third semiconductor layer SCL0, the first semiconductor layer SCL1, the light emitting layer EML, the second semiconductor layer SCL2, and the electrode layer ETL are sequentially stacked in the first oblique direction DR_D1, the light emitting layer EML, the second semiconductor layer SCL2, and the electrode layer ETL may be covered only with the first insulating layer INS1, and the third semiconductor layer SCL0 and the electrode layer ETL may be exposed.

The first electrode ELT1 may be disposed on a first end of the light emitting element LD and may be connected to the first end of the light emitting element LD. For example, the first electrode ELT1 may be disposed on the third semiconductor layer SCL0 and the first insulating layer INS1, and may contact a portion of the third semiconductor layer SCL0 exposed by the first insulating layer INS1. In case that the first semiconductor layer SCL1 is partially exposed by the first insulating layer INS1, the first electrode ELT1 may contact the first semiconductor layer SCL1. In an embodiment, the first electrode ELT1 may be connected to the first semiconductor layer SCL1 through another conductive element (not shown). As shown in FIG. 4, the first electrode ELT1 may contact or be connected to the second power source line PL2 through a contact hole penetrating the passivation layer PSV. The first electrode ELT1 may electrically connect the first end of the light emitting element LD and the second power source line PL2. The first electrode ELT1 may be a cathode electrode.

The second electrode ELT2 may be disposed on a second end of the light emitting element LD and may be connected to the second end of the light emitting element LD. For example, the second electrode ELT2 may be disposed on the electrode layer ETL and the first insulating layer INS1, and may contact a portion of the electrode layer ETL exposed by the first insulating layer INS1. As shown in FIG. 4, the second electrode ELT2 may contact or be connected to the second terminal TE2 of the transistor T (or the first transistor T1) through a contact hole penetrating the passivation layer PSV. The second electrode ELT2 may electrically connect the second end of the light emitting element LD and the transistor T (or the first transistor T1). The second electrode ELT2 may be an anode electrode.

According to an embodiment, as shown in FIG. 5, in case that the dedicated substrate SAP is disposed entirely on the substrate SUB, the first electrode ELT1 may connect or be connected to the second power source line PL2 through a contact hole penetrating the dedicated substrate SAP and the passivation layer PSV. Similarly, the second electrode ELT2 may be connected to the transistor T (or the first transistor T1) through a contact hole penetrating the dedicated substrate SAP and the passivation layer PSV.

The first electrode ELT1 and the second electrode ELT2 may include a transparent conductive material such as indium tin oxide (ITO), indium zinc oxide (IZO), zinc oxide (ZnO), indium gallium zinc oxide (IGZO), the like, or a mixture thereof.

As described above, the light emitting element LD may include the third semiconductor layer SCL0, the first semiconductor layer SCL1, the light emitting layer EML, the second semiconductor layer SCL2, the electrode layer ETL, and the first insulating layer INS1 sequentially stacked on the dedicated substrate SAP. Instead of separately manufacturing the light emitting element LD and arranging or mounting (or bonding) the light emitting element LD on the lower panel BP, in the disclosure, the light emitting element LD may be disposed (or stacked) on the lower panel BP (or the dedicated substrate SAP) in the form of a layer. Accordingly, a process of aligning the light emitting element LD can be omitted, and a manufacturing process of the display device can be simplified. Since there is no problem in that light emitting elements LD are not uniformly aligned, a yield of the display device can be improved.

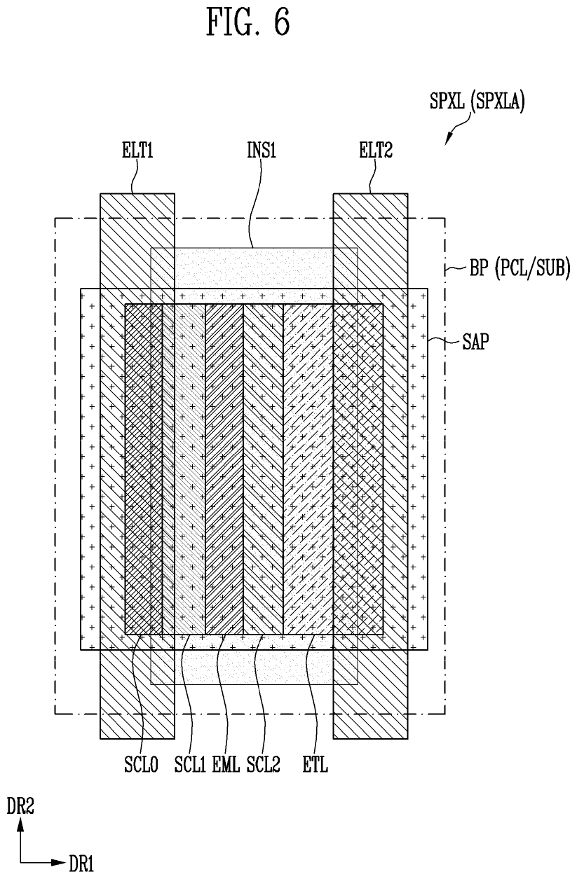

FIG. 6 is a schematic plan view illustrating a pixel of FIG. 2 according to an embodiment.

Referring to FIGS. 2 to 6, in a sub-pixel area SPXLA, the dedicated substrate SAP may be disposed on the lower panel BP (the pixel circuit layer PCL or the substrate SUB). The dedicated substrate SAP may be positioned at a center of an area of the lower panel BP, but the disclosure is not limited thereto. Also, in a plan view, the dedicated substrate SAP may have a rectangular shape in a plan view, but the disclosure is not limited thereto.

Each of the third semiconductor layer SCL0, the first semiconductor layer SCL1, the light emitting layer EML, the second semiconductor layer SCL2, and the electrode layer ETL may have a width (e.g., a specific width) in the first direction DR1 and extend in the second direction DR2. The third semiconductor layer SCL0, the first semiconductor layer SCL1, the light emitting layer EML, the second semiconductor layer SCL2, and the electrode layer ETL may be located only within the dedicated substrate SAP.

In a plan view, the third semiconductor layer SCL0, the first semiconductor layer SCL1, the light emitting layer EML, the second semiconductor layer SCL2, and the electrode layer ETL may be arranged in the first direction DR1 while partially overlapping each other.

The third semiconductor layer SCL0 may be disposed adjacent to a side of the dedicated substrate SAP. The first semiconductor layer SCL1 may be positioned on a side of the third semiconductor layer SCL0 in the first direction DR1, and the first semiconductor layer SCL1 may partially overlap the third semiconductor layer SCL0 in the third direction DR3. The light emitting layer EML may be positioned on a side of the first semiconductor layer SCL1 in the first direction DR1, and the light emitting layer EML may partially overlap the first semiconductor layer SCL1 in the third direction DR3. The second semiconductor layer SCL2 may be positioned on a side of the light emitting layer EML in the first direction DR1, and the second semiconductor layer SCL2 may partially overlap the light emitting layer EML in the third direction DR3. The electrode layer ETL may be positioned on a side of the second semiconductor layer SCL2 in the first direction DR1, and the electrode layer ETL may partially overlap the second semiconductor layer SCL2 in the third direction DR3.

As shown in FIG. 6, in the second direction DR2 (and a direction opposite to the second direction DR2), ends (or side surfaces) of the third semiconductor layer SCL0, the first semiconductor layer SCL1, the light emitting layer EML, the second semiconductor layer SCL2, and the electrode layer ETL may be aligned with each other, but the disclosure is not limited thereto.

The first insulating layer INS1 may cover the first semiconductor layer SCL1, the light emitting layer EML, and the second semiconductor layer SCL2. A length of the first insulating layer INS1 in the second direction DR2 may be greater than lengths of the first semiconductor layer SCL1, the light emitting layer EML, and the second semiconductor layer SCL2 in the second direction DR2. The first insulating layer INS1 may completely cover the first semiconductor layer SCL1, the light emitting layer EML, and the second semiconductor layer SCL2 in the second direction DR2. According to an embodiment, the first insulating layer INS1 may extend across the dedicated substrate SAP in the second direction DR2.

The first electrode ELT1 may overlap the third semiconductor layer SCL0 in the third direction DR3 and may contact a portion of the third semiconductor layer SCL0 exposed by the first insulating layer INS1. The second electrode ELT2 may overlap the electrode layer ETL in the third direction DR3 and may contact a portion of the electrode layer ETL exposed by the first insulating layer INS1.

Each of the first electrode ELT1 and the second electrode ELT2 may have a width (e.g., a specific width) in the first direction DR1 and may extend in the second direction DR2. However, the first electrode ELT1 and the second electrode ELT2 are not limited thereto, and an arrangement and/or shape of each of the first electrode ELT1 and the second electrodes ELT2 may be variously changed within a range of contacting the third semiconductor layer SCL0 or the electrode layer ETL.

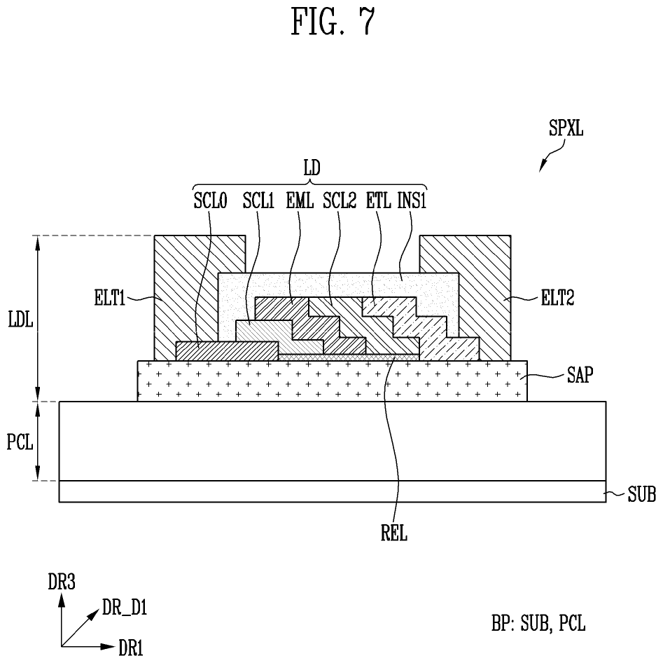

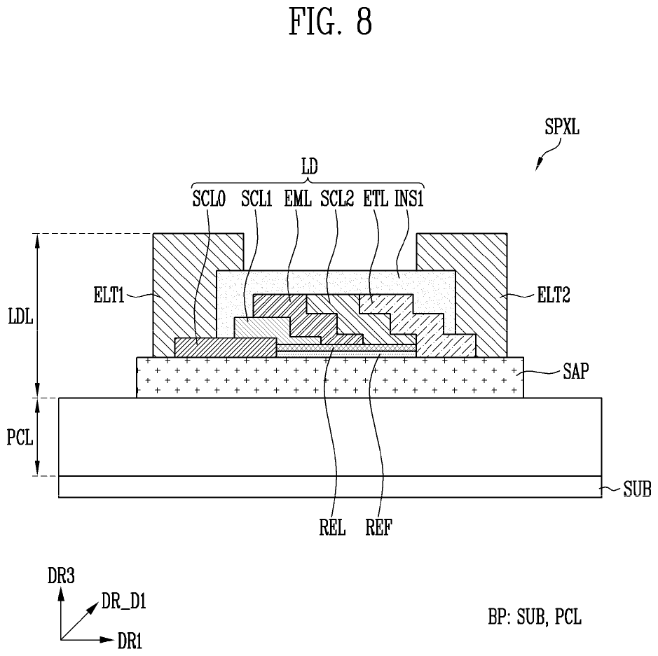

FIGS. 7 and 8 are schematic cross-sectional views illustrating the sub-pixel of FIG. 2 according to an embodiment.

Referring to FIGS. 2 to 8, except for a reinforcing layer REL and a reflective layer REF, the sub-pixel SPXL of FIG. 7 and the sub-pixel SPXL of FIG. 8 may be substantially the same as or similar to the sub-pixel SPXL of FIGS. 3 to 5. Therefore, duplicate descriptions will not be repeated.

As shown in FIG. 7, the sub-pixel SPXL may further include the reinforcing layer REL. The reinforcing layer REL may be disposed on the dedicated substrate SAP adjacent to the third semiconductor layer SCL0. The reinforcing layer REL and the third semiconductor layer SCL0 may be disposed on substantially a same layer. The reinforcing layer REL may be disposed between the dedicated substrate SAP and the first and second semiconductor layers SCL1 and SCL2 (and the light emitting layer EML).

The reinforcing layer REL may include at least one insulating material selected from silicon oxide (SiOₓ) (for example, SiO₂), silicon nitride (SiNₓ) (for example, Si₃N₄), aluminum oxide (AlₓO_{y}) (for example, Al₂O₃), titanium oxide (TiₓO_{y}) (for example, TiO₂), and hafnium oxide (HfOₓ), or other insulating material.

The first semiconductor layer SCL1 may be disposed on the third semiconductor layer SCL0 and the reinforcing layer REL, and a portion of the first semiconductor layer SCL1 may contact the reinforcing layer REL. The light emitting layer EML may be disposed on the first semiconductor layer SCL1 and the reinforcing layer REL, and a portion of the light emitting layer EML may contact the reinforcing layer REL. The second semiconductor layer SCL2 may be disposed on the light emitting layer EML and the reinforcing layer REL, and a portion of the second semiconductor layer SCL2 may contact the reinforcing layer REL.

The reinforcing layer REL may enhance adhesion between the dedicated substrate SAP and the first semiconductor layer SCL1, the light emitting layer EML, and the second semiconductor layer SCL2, and may allow the light emitting element LD to be more stably formed (or stacked).

In FIG. 7, the electrode layer ETL is shown not contacting an upper surface of the reinforcing layer REL, but the disclosure is not limited thereto. For example, the reinforcing layer REL may further extend in the first direction DR1, the electrode layer ETL may be formed on the reinforcing layer REL, and the electrode layer ETL may not contact the dedicated substrate SAP.

As shown in FIG. 8, the sub-pixel SPXL may further include a reflective layer REF. The reflective layer REF may be disposed on the dedicated substrate SAP adjacent to the third semiconductor layer SCL0. The reflective layer REF and the third semiconductor layer SCL0 may be disposed on substantially a same layer. The reflective layer REF may be disposed between the dedicated substrate SAP and the first and second semiconductor layers SCL1 and SCL2 (and the light emitting layer EML). In case that the reinforcing layer REL is formed, the reflective layer REF may be disposed between the dedicated substrate SAP and the reinforcing layer REL.

The reflective layer REF may include a conductive material having a reflectance so that light emitted from the light emitting element LD proceeds in an image display direction of the display device (for example, the third direction DR3). For example, the reflective layer REF may include a material selected from copper (Cu), molybdenum (Mo), tungsten (W), aluminum neodymium (AlNd), titanium (Ti), aluminum (Al), silver (Ag), the like, and an alloy thereof. However, the disclosure is not limited thereto, and within a range of reflecting light, the reflective layer REF may include various other materials.

In FIG. 8, the reflective layer REF is shown completely overlapping the reinforcing layer REL in the third direction DR3, but the disclosure is not limited thereto. For example, a width of the reflective layer REF in the first direction DR1 may be different from a width of the reinforcing layer REL in the first direction DR1.

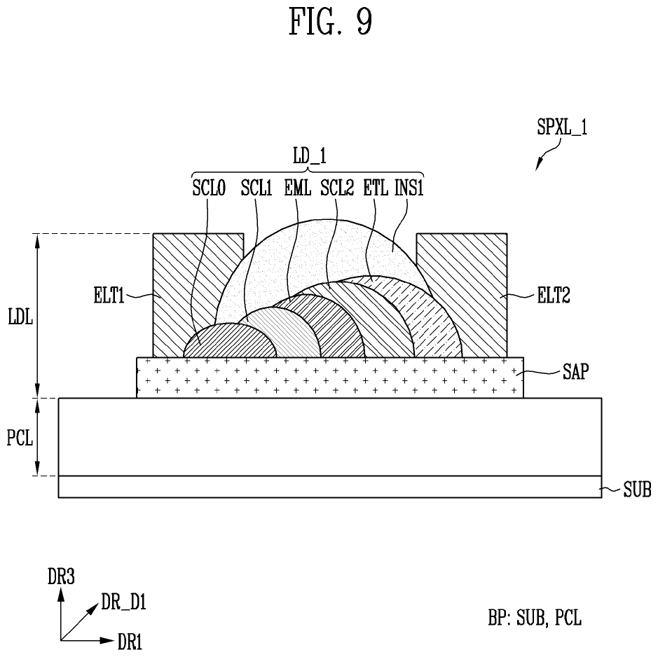

FIGS. 9, 10, and 11 are schematic cross-sectional views illustrating the sub-pixel of FIG. 2 according to an embodiment.

Referring to FIGS. 2 to 11, except for a shape of some components such as a third semiconductor layer SCL0 included in a light emitting element LD_1, a sub-pixel SPXL_1 of FIGS. 9 to 11 may be substantially the same as or similar to the sub-pixel SPXL of FIGS. 3, 7, and 8. Therefore, duplicate descriptions will not be repeated.

In a cross-sectional view, at least some of the third semiconductor layer SCL0, the first semiconductor layer SCL1, the light emitting layer EML, the second semiconductor layer SCL2, the electrode layer ETL, and the first insulating layer INS1 may have a curved surface. For example, in a cross-sectional view, each of the third semiconductor layer SCL0, the first semiconductor layer SCL1, the light emitting layer EML, the second semiconductor layer SCL2, the electrode layer ETL, and the first insulating layer INS1 may have an elliptical shape in a plan view.

Depending on a type of process technique of epitaxial growth, process conditions, and sizes of components (for example, the third semiconductor layer SCL0, the first semiconductor layer SCL1, or the like), at least some of the third semiconductor layer SCL0, the first semiconductor layer SCL1, the light emitting layer EML, the second semiconductor layer SCL2, the electrode layer ETL, and the first insulating layer INS1 may have an elliptical shape in a plan view.

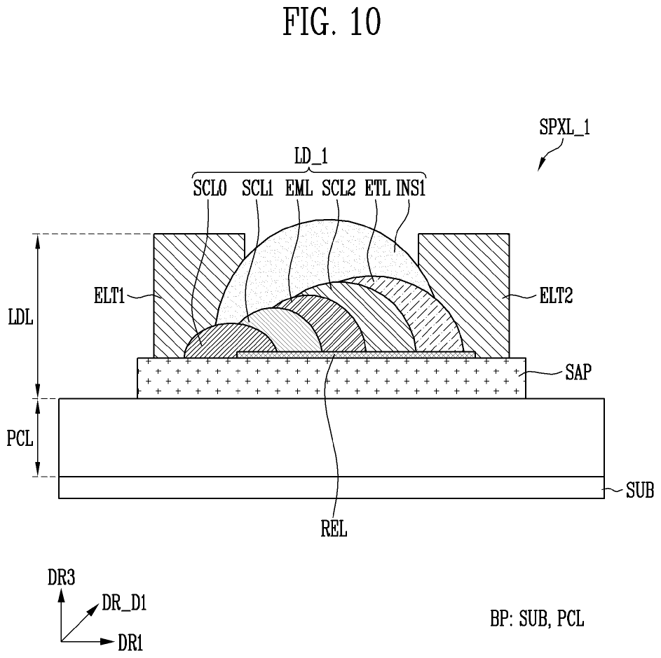

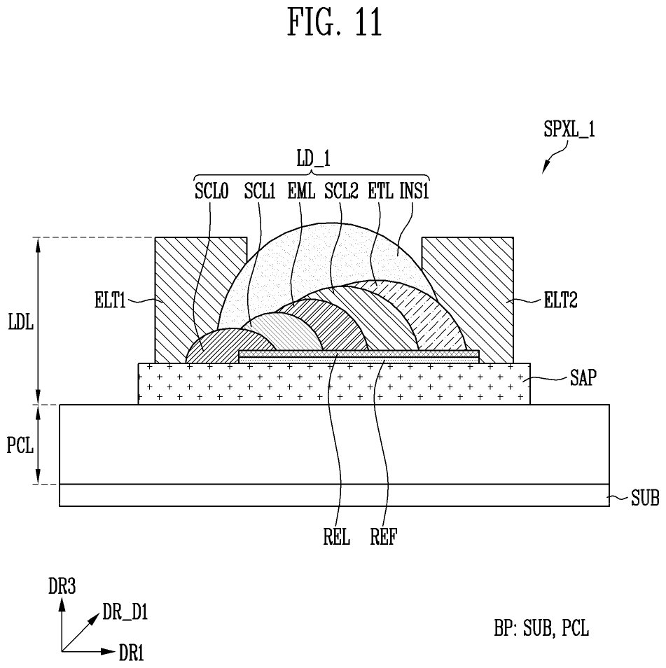

As shown in FIG. 10, the sub-pixel SPXL_1 may further include a reinforcing layer REL. As shown in FIG. 11, the sub-pixel SPXL_1 may further include a reflective layer REF.

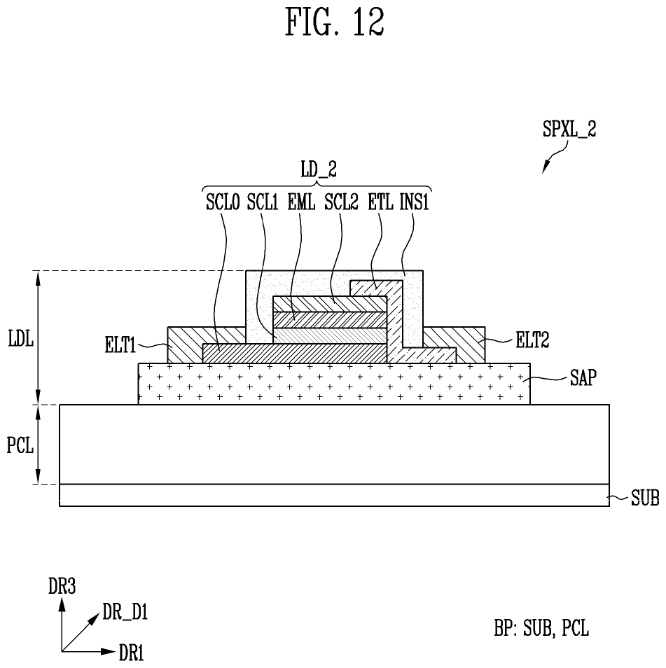

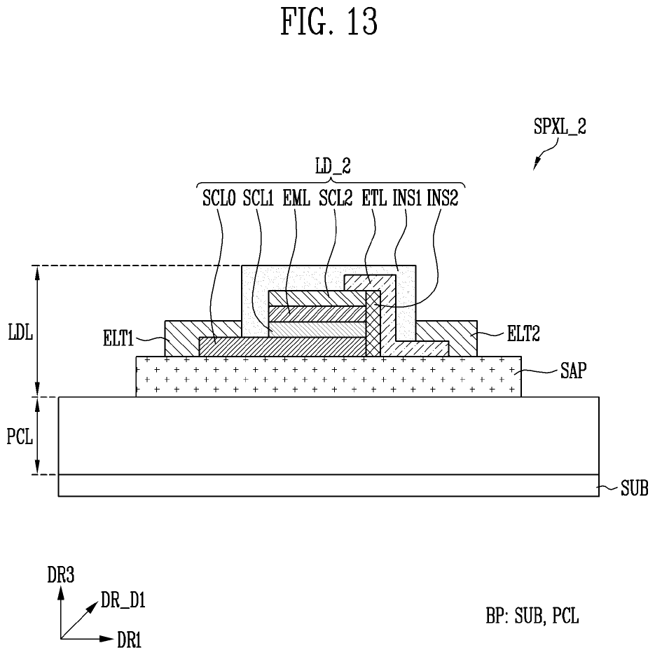

FIGS. 12 and 13 are schematic cross-sectional views illustrating the sub-pixel of FIG. 2 according to an embodiment.

Referring to FIGS. 2 to 5, 12, and 13, except for an arrangement of a first semiconductor layer SCL1, a light emitting layer EML, and a second semiconductor layer SCL2 included in a light emitting element LD_2, a sub-pixel SPXL_2 of FIGS. 12 and 13 may be substantially the same as or similar to the sub-pixel SPXL of FIGS. 3 to 5. Therefore, duplicate descriptions will not be repeated.

The light emitting element LD_2 may include a third semiconductor layer SCL0, a first semiconductor layer SCL1, a light emitting layer EML, a second semiconductor layer SCL2, an electrode layer ETL, and a first insulating layer INS1. The third semiconductor layer SCL0, the first semiconductor layer SCL1, the light emitting layer EML, and the second semiconductor layer SCL2 may be sequentially stacked on the dedicated substrate SAP in the third direction DR3.

The first semiconductor layer SCL1 may be disposed on the third semiconductor layer SCL0. The first semiconductor layer SCL1 may expose a portion of the third semiconductor layer SCL0. A width of the first semiconductor layer SCL1 in the first direction DR1 may be less than a width of the third semiconductor layer SCL0 in the first direction DR1. The first semiconductor layer SCL1 may be directly disposed only on the third semiconductor layer SCL0, and the first semiconductor layer SCL1 may be spaced apart from the dedicated substrate SAP without contacting the dedicated substrate SAP.

The light emitting layer EML may be disposed on the first semiconductor layer SCL1. A width of the light emitting layer EML in the first direction DR1 and the width of the first semiconductor layer SCL1 in the first direction DR1 may be the same, but the disclosure is not limited thereto. For example, the width of the light emitting layer EML in the first direction DR1 may be less than the width of the first semiconductor layer SCL1 in the first direction DR1. The light emitting layer EML may be directly disposed only on the first semiconductor layer SCL1, and the light emitting layer EML may be spaced apart from the dedicated substrate SAP.

The second semiconductor layer SCL2 may be disposed on the light emitting layer EML. A width of the second semiconductor layer SCL2 in the first direction DR1 and the width of the light emitting layer EML in the first direction DR1 may be the same, but the disclosure is not limited thereto. For example, the width of the second semiconductor layer SCL2 in the first direction DR1 may be less than the width of the light emitting layer EML in the first direction DR1. The second semiconductor layer SCL2 may be directly disposed only on the light emitting layer EML, and the second semiconductor layer SCL2 may be spaced apart from the dedicated substrate SAP.

The electrode layer ETL may be disposed on the second semiconductor layer SCL2 and the dedicated substrate SAP. The electrode layer ETL may partially overlap the second semiconductor layer SCL2 in the third direction DR3, and a portion of the electrode layer ETL may contact the dedicated substrate SAP.

The first insulating layer INS1 may cover the third semiconductor layer SCL0, the first semiconductor layer SCL1, the light emitting layer EML, and the second semiconductor layer SCL2. The first insulating layer INS1 may partially expose the third semiconductor layer SCL0 and the electrode layer ETL at ends of the light emitting element LD_2 (e.g., an end of the light emitting element LD_2 and another end of the light emitting element LD_2).

In an embodiment, the light emitting element LD_2 (or the sub-pixel SPXL_2) may further include a second insulating layer INS2.

The second insulating layer INS2 (an insulating thin film or an interlayer insulating layer) may surround at least one side surface of a stacked structure composed of the third semiconductor layer SCL0, the first semiconductor layer SCL1, the light emitting layer EML, and the second semiconductor layer SCL2. For example, as shown in FIG. 13, the second insulating layer INS2 may be disposed or interposed between the at least one side surface of the stacked structure and the electrode layer ETL. Although the second insulating layer INS2 is shown as being disposed between a side surface of the second semiconductor layer SCL2 and the electrode layer ETL, the disclosure is not limited thereto. The second insulating layer INS2 may not be disposed on at least a part of the side surface of the second semiconductor layer SCL2.

The second insulating layer INS2 may prevent a short circuit between the third semiconductor layer SCL0 (and/or the first semiconductor layer SCL1) and the electrode layer ETL (and the second semiconductor layer SCL2).

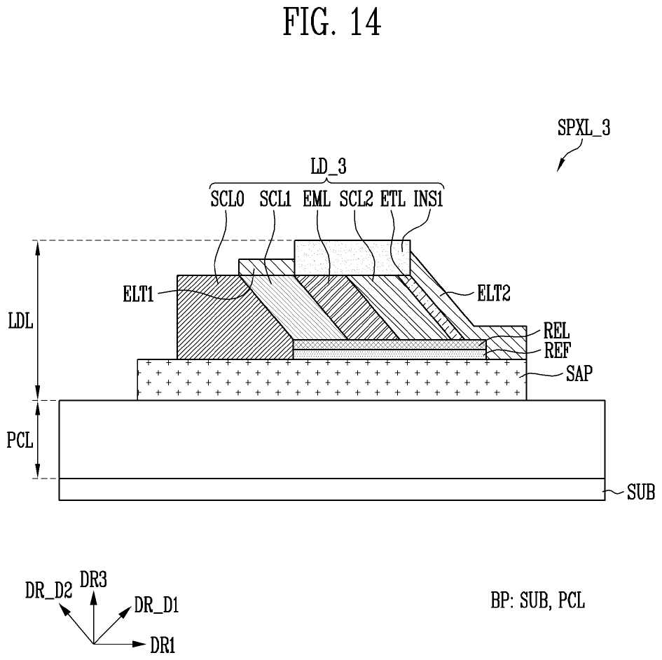

FIG. 14 is a schematic cross-sectional view illustrating the sub-pixel of FIG. 2 according to an embodiment.

Referring to FIGS. 2 to 8 and 14, except for a shape of a light emitting element LD_3, a sub-pixel SPXL_3 of FIG. 14 may be substantially the same as or similar to the sub-pixel SPXL of FIGS. 3 to 8. In order to avoid duplicate descriptions, different points from the above-described embodiments (for example, the embodiments of FIGS. 3 to 8) will be described.

The light emitting element LD_3 may be disposed on a dedicated substrate SAP, and include a third semiconductor layer SCL0, a first semiconductor layer SCL1, a light emitting layer EML, a second semiconductor layer SCL2, an electrode layer ETL, and a first insulating layer INS1. The third semiconductor layer SCL0, the first semiconductor layer SCL1, the light emitting layer EML, the second semiconductor layer SCL2, and the electrode layer ETL may be laterally grown on the dedicated substrate SAP in the first oblique direction DR_D1. The light emitting element LD_3 may further include a reinforcing layer REL and a reflective layer REF.

The third semiconductor layer SCL0 may include an inclined surface inclined with respect to an upper surface of the dedicated substrate SAP (or the substrate SUB).

The first semiconductor layer SCL1 may be disposed on the inclined surface of the third semiconductor layer SCL0 and the dedicated substrate SAP (or the reflected layer REF). The first semiconductor layer SCL1 may have a thickness (e.g., a substantially constant thickness) in the first oblique direction DR_D1 perpendicular to the inclined surface (or a second oblique direction DR_D2 parallel to the inclined surface). The second oblique direction DR_D2 may intersect the first oblique direction DR1_D1.

The light emitting layer EML may be disposed on an inclined surface of the first semiconductor layer SCL1 and the dedicated substrate (or the reflective layer RED). The light emitting layer EML may have a thickness (e.g., a substantially constant thickness) in the first oblique direction DR_D1.

The second semiconductor layer SCL2 may be disposed on an inclined surface of the light emitting layer EML and the dedicated substrate (or the reflective layer RED). The second semiconductor layer SCL2 may have a thickness (e.g., a substantially constant thickness) in the first oblique direction DR_D1.

The electrode layer ETL may be disposed on an inclined surface of the second semiconductor layer SCL2 and the dedicated substrate (or the reflective layer RED). The electrode layer ETL may have a thickness (e.g., a substantially constant thickness) in the first oblique direction DR_D1.

Upper surfaces of the first semiconductor layer SCL1, the light emitting layer EML, the second semiconductor layer SCL2, and the electrode layer ETL may be aligned and coplanar with each other. Similarly, lower surfaces of the first semiconductor layer SCL1, the light emitting layer EML, the second semiconductor layer SCL2, and the electrode layer ETL may be aligned and coplanar with each other. The lower surfaces of the first semiconductor layer SCL1, the light emitting layer EML, the second semiconductor layer SCL2, and the electrode layer ETL may contact an upper surface of the reinforcing layer REL. According to an embodiment, the reinforcing layer REL and the reflective layer REF may be omitted, and the lower surfaces of the first semiconductor layer SCL1, the light emitting layer EML, the second semiconductor layer SCL2, and the electrode layer ETL may contact the dedicated substrate SAP.

The first insulating layer INS1 may be disposed on the light emitting layer EML, the second semiconductor layer SCL2, and the electrode layer ETL, and may cover the light emitting layer EML and the second semiconductor layer SCL2. According to an embodiment, as described with reference to FIG. 3, the first insulating layer INS1 may also be disposed on at least a portion of the first semiconductor layer SCL1 or may also be disposed on a portion of the third semiconductor layer SCL0.

The first electrode ELT1 may be disposed on a first portion (or the first end) of the light emitting element LD_3 and may be electrically connected to the first semiconductor layer SCL1. For example, as shown in FIG. 14, the first electrode ELT1 may be disposed on the first semiconductor layer SCL1 and may contact at least a portion of the first semiconductor layer SCL1 exposed by the first insulating layer INS1. However, the disclosure is not limited thereto, and the first electrode ELT1 may be disposed on at least a portion of the third semiconductor layer SCL0 and may contact the third semiconductor layer SCL0.

The second electrode ELT2 may be disposed on a second portion (or the second end) of the light emitting element LD and may be electrically connected to the second semiconductor layer SCL2. For example, the second electrode ELT2 may be disposed on an inclined surface of the electrode layer ETL and the dedicated substrate (or the reflective layer RED) and may contact the inclined surface of the electrode layer ETL exposed by the first insulating layer INS1.

As described above, the light emitting element LD_3 may include the third semiconductor layer SCL0, the first semiconductor layer SCL1, the light emitting layer EML, the second semiconductor layer SCL2, the electrode layer ETL, and the first insulating layer INS1 laterally grown on the dedicated substrate SAP.

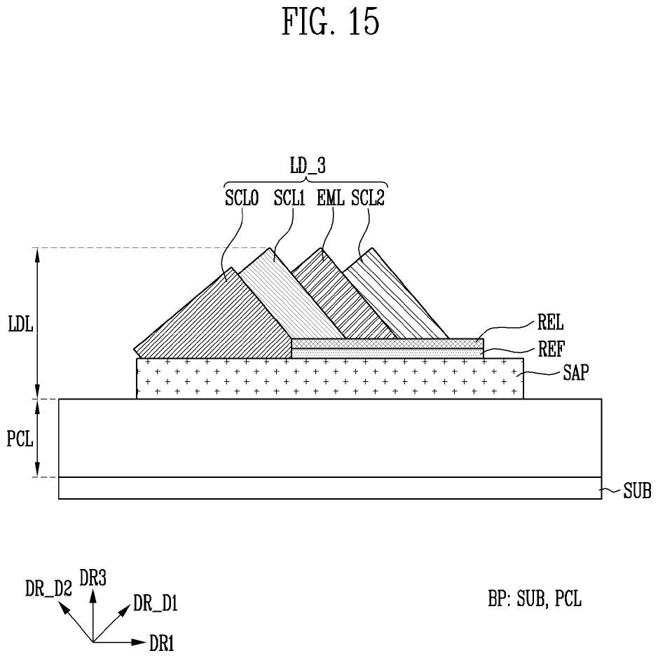

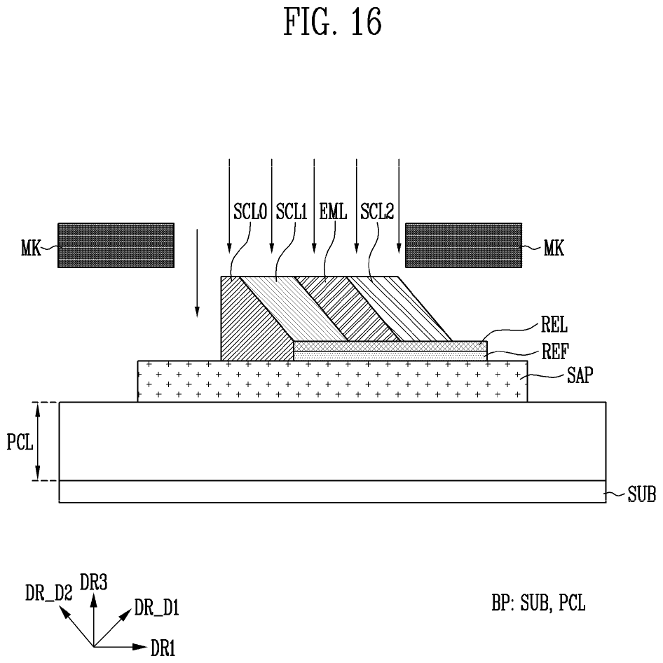

FIGS. 15 and 16 are schematic diagrams for explaining a method of forming a light emitting element included in the sub-pixel of FIG. 14 according to an embodiment.

First, referring to FIGS. 14 and 15, the pixel circuit layer PCL may be formed on the substrate SUB, and the dedicated substrate SAP may be formed on the pixel circuit layer PCL.

After forming the dedicated substrate SAP, the third semiconductor layer SCL0, the first semiconductor layer SCL1, the light emitting layer EML, and the second semiconductor layer SCL2 may be sequentially formed on the dedicated substrate SAP. The third semiconductor layer SCL0, the first semiconductor layer SCL1, the light emitting layer EML, and the second semiconductor layer SCL2 may be formed through an epitaxial growth technique.

In an embodiment, the third semiconductor layer SCL0, the first semiconductor layer SCL1, the light emitting layer EML, and the second semiconductor layer SCL2 may be sequentially formed on the dedicated substrate SAP through a lateral growth technique. For example, the third semiconductor layer SCL0 may be grown to have a triangular-shaped cross section through a lateral growth technique. The first semiconductor layer SCL1 may be grown to have a diamond-shaped cross section on the inclined surface of the third semiconductor layer SCL0, the light emitting layer EML may be grown to have a diamond-shaped cross section on the inclined surface of the first semiconductor layer SCL1, and the second semiconductor layer SCL2 may be grown to have a diamond-shaped cross section on the inclined surface of the light emitting layer EML.

According to an embodiment, before forming the first semiconductor layer SCL1, the reflective layer REF and the reinforcing layer REL may be sequentially formed on the dedicated substrate SAP, however, the disclosure is not limited thereto.

After sequentially forming the reflective layer REF and the reinforcing layer REL, the third semiconductor layer SCL0, the first semiconductor layer SCL1, the light emitting layer EML, and the second semiconductor layer SCL2 may be collectively etched using a mask MK. For example, an anisotropic etching method (or a dry etching method) may be applied for the above etching.

For example, as shown in FIG. 16, a portion (for example, a left portion and an upper portion) of the third semiconductor layer SCL0 exposed by the mask MK may be removed, and portions (for example, upper portions) of the first semiconductor layer SCL1, the light emitting layer EML, and the second semiconductor layer SCL2 exposed by the mask MK may be removed. Through collective etching, upper surfaces of the third semiconductor layer SCL0, the first semiconductor layer SCL1, the light emitting layer EML, and the second semiconductor layer SCL2 may be positioned on a same plane.

After exposing the upper surfaces of the third semiconductor layer SCL0, the first semiconductor layers SCL1, the light emitting layer EML, and the second semiconductor layer SCL2, the electrode layer ETL may be formed on the inclined surface of the second semiconductor layer SCL2, and the first insulating layer INS1 may be formed at least on the light emitting layer EML and the second semiconductor layer SCL2. Through this, the light emitting element LD_3 shown in FIG. 14 may be formed.

After forming the light emitting element LD_3, the first electrode ELT1 and the second electrode ELT2 may be formed. The first electrode ELT1 and the second electrode ELT2 may be simultaneously formed through a same process, but the disclosure is not limited thereto. The first electrode ELT1 and the second electrode ELT2 may be formed through different processes.

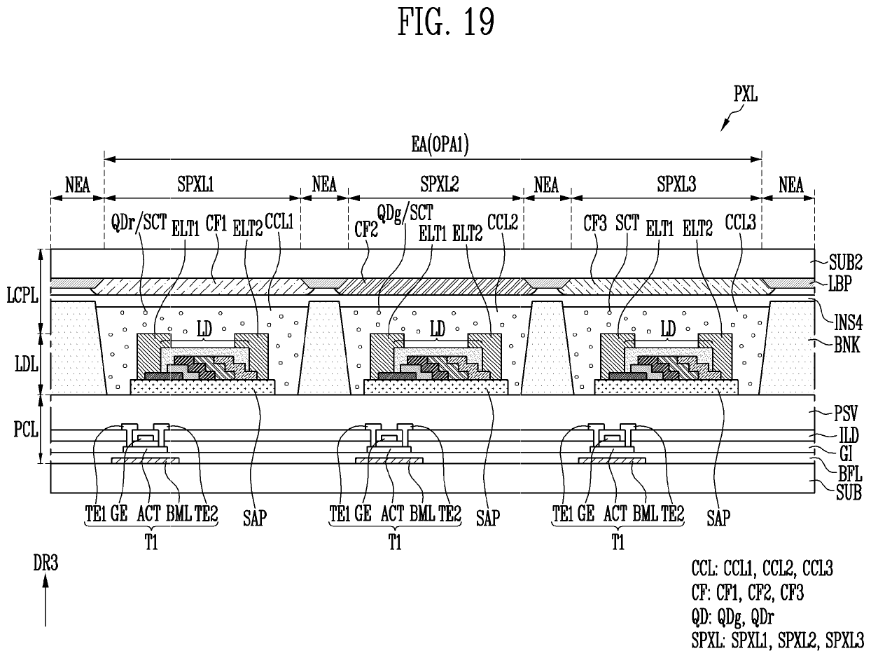

FIGS. 17, 18, and 19 are schematic cross-sectional views illustrating a pixel included in the display device of FIG. 1 according to an embodiment. FIG. 18 shows a modified embodiment of FIG. 17 in relation to a location of the dedicated substrate SAP. FIG. 19 shows a modified example of FIG. 17 in relation to a position of color filters CF. For example, FIG. 17 shows an embodiment in which the color filters CF are positioned through a continuous process, and FIG. 19 shows an embodiment in which a second substrate SUB2 including the color filters CF is positioned on the light emitting element layer LDL through a bonding process. Regarding the embodiments of FIGS. 17 to 19, differences from the above-described embodiments (for example, the embodiments of FIGS. 3 to 14) will be described in order to avoid redundant description. FIGS. 17 to 19 show an embodiment to which the light emitting element LD of FIGS. 3 to 5 is applied, but the disclosure is not limited thereto, and the embodiments of FIGS. 7 to 14 may be applied to FIGS. 17 to 19.

Referring to FIGS. 3 and 17, the sub-pixel SPXL (or the display device) may further include a light conversion layer LCPL disposed on the light emitting element layer LDL.

The light conversion layer LCPL may include a bank BNK, a color conversion layer CCL, and the color filters CF.

The bank BNK may be disposed on the pixel circuit layer PCL (or the passivation layer PSV). The bank BNK may be positioned in a non-emission area NEA and may be a structure defining a position where the color conversion layer CCL is to be supplied.

The bank BNK may include an organic material. According to an embodiment, the bank BNK may include a light blocking material. For example, the bank BNK may be a black matrix. According to an embodiment, the bank BNK may include at least one light blocking material and/or reflective material so that light emitted from the color conversion layer CCL proceeds in the third direction DR3 (or the image display direction of the display device), thereby improving light output efficiency of the color conversion layer CCL (or the sub-pixel SPXL).

The color conversion layer CCL may be disposed on the light emitting element layer LDL (or the light emitting element LD) in a region surrounded by the bank BNK. The color conversion layer CCL may include a first color conversion layer CCL1, a second color conversion layer CCL2, and a third color conversion layer CCL3.

The color conversion layer CCL may include color conversion particles QD (or wavelength conversion particles) corresponding to a color (e.g., a specific color). For example, the color conversion layer CCL may include the color conversion particles QD that convert light of a first color (or a first wavelength band) incident from the light emitting element LD into light of a second color (a specific color or a second wavelength band).

In case that the first sub-pixel SPXL1 is a red pixel (or red sub-pixel), the first color conversion layer CCL1 of the first sub-pixel SPXL1 may include first color conversion particles QDr of red quantum dots that convert light of a first color emitted from the light emitting element LD into light of a second color, for example, red light.

In case that the second sub-pixel SPXL2 is a green pixel (or green sub-pixel), the second color conversion layer CCL2 of the second sub-pixel SPXL2 may include second color conversion particles QDg of green quantum dots that convert light of the first color emitted from the light emitting element LD into light of a third color, for example, green light.

In case that the third sub-pixel SPXL3 is a blue pixel (or blue sub-pixel), the third color conversion layer CCL3 of the third sub-pixel SPXL3 may include color conversion particles of blue quantum dots that convert light of the first color emitted from the light emitting element LD into light of a fourth color, for example, blue light.

According to an embodiment, in case that the third sub-pixel SPXL3 is a blue pixel (or blue sub-pixel) and the light emitting element LD emits blue-based light, the third sub-pixel SPXL3 may include a light scattering layer including light scattering particles SCT. The light scattering layer described above may be omitted according to embodiments. According to another embodiment, in case that the third subpixel SPXL3 is a blue pixel (or blue sub-pixel), a transparent polymer may be provided instead of the third color conversion layer CCL3.

A fourth insulating layer INS4 may be disposed on the color conversion layer CCL and the bank BNK. The fourth insulating layer INS4 may be provided on an entire area of the substrate SUB and cover the bank BNK and the color conversion layer CCL. The fourth insulating layer INS4 may include an inorganic material or an organic material. According to an embodiment, the fourth insulating layer INS4 may totally transmit light emitted from the color conversion layer CCL (for example, light traveling in an oblique direction) by using a difference in refractive index with an adjacent component, and may improve light output efficiency of the sub-pixel SPXL. The fourth insulating layer INS4 may have a relatively low refractive index compared to the color conversion layer CCL.

According to an embodiment, the fourth insulating layer INS4 may alleviate a step difference caused by components disposed under the fourth insulating layer INS4 and may have a flat surface.

According to an embodiment, a first and second capping layers may be disposed above and below the fourth insulating layer INS4. The first and second capping layers may include an inorganic material. The first and second capping layers may prevent moisture (or a solution used in a subsequent process) from penetrating into components disposed thereunder (for example, the color conversion layer CCL and the fourth insulating layer INS4).

A color filter layer may be disposed on the fourth insulating layer INS4.

The color filter layer may include the color filter CF corresponding to each color of adjacent sub-pixels SPXL. The color filter CF may include a first color filter CF1, a second color filter CF2, and a third color filter CF3. For example, the first color filter CF1 may be disposed on the first color conversion layer CCL1 of the first sub-pixel SPXL1, the second color filter CF2 may be disposed on the second color conversion layer CCL2 of the second sub-pixel SPXL2, and the third color filter CF3 may be disposed on the third color conversion layer CCL3 of the third sub-pixel SPXL3. Each of the first, second, and third color filters CF1, CF2, and CF3 may include a color filter material that selectively transmits light of a color (e.g., a specific color) converted in the color conversion layer CCL. For example, the first color filter CF1 may be a red color filter, the second color filter CF2 may be a green color filter, and the third color filter CF3 may be a blue color filter. The color filter CF may be provided on a surface of the fourth insulating layer INS4 corresponding to the color conversion layer CCL.

As shown in FIG. 17, the first, second, and third color filters CF1, CF2, and CF3 may be disposed to overlap with each other in the non-emission area NEA in the third direction DR3 to block light interference between adjacent sub-pixels SPXL. According to an embodiment, a separate light blocking pattern may be disposed in the non-emission area NEA instead of a laminated structure of each of the first, second, and third color filters CF1, CF2, and CF3.

A fifth insulating layer INS5 may be disposed on the color filter layer. The fifth insulating layer INS5 may include an inorganic material or an organic material. The fifth insulating layer INS5 may entirely cover components positioned below to prevent moisture or the like from flowing into the color filter layer and the light emitting element layer LDL from an outside. In an embodiment, the fifth insulating layer INS5 may be formed of multiple layers. For example, the fifth insulating layer INS5 may include at least two inorganic layers and at least one organic layer interposed between the at least two inorganic layers. However, a material and/or structure of the fifth insulating layer INS5 may be variously changed. Also, according to an embodiment, at least one overcoat layer, a filler layer, and/or an upper substrate may be further disposed on the fifth insulating layer INS5.

In the above-described embodiment, an embodiment in which the color filter layer may be directly formed on the color conversion layer CCL has been described, but the disclosure is not limited thereto. According to an embodiment, as shown in FIG. 19, the color filter layer may be formed on a separate substrate, for example, the second substrate SUB2 and bonded to the color conversion layer CCL through an adhesive material. For example, the adhesive material may be an optically transparent adhesive layer (optically clear adhesive), but the disclosure is not limited thereto.

The second substrate SUB2 (or upper substrate) may constitute an encapsulation substrate and/or a window member of the display device. In an embodiment, the second substrate SUB2 and the substrate SUB may be made of a same material. In another embodiment, the second substrate SUB2 and the substrate SUB may include different materials.

Referring to FIG. 19, the color filter CF may be disposed under the second substrate SUB2 to face the light emitting element layer LDL.

A light blocking pattern LBP may be positioned adjacent to the color filter CF. The light blocking pattern LBP may be disposed under the second substrate SUB2 corresponding to the non-emission area NEA. The light blocking pattern LBP may be a black matrix.

In case that the sub-pixel SPXL includes the light conversion layer LCPL on the light emitting element layer LDL, for example, in case that the sub-pixel SPXL includes the color conversion layer CCL and the color filter CF disposed on the light emitting element LD, light having excellent color reproducibility may be emitted through the color conversion layer CCL and the color filter CF, and light output efficiency of the sub-pixel SPXL may be improved.

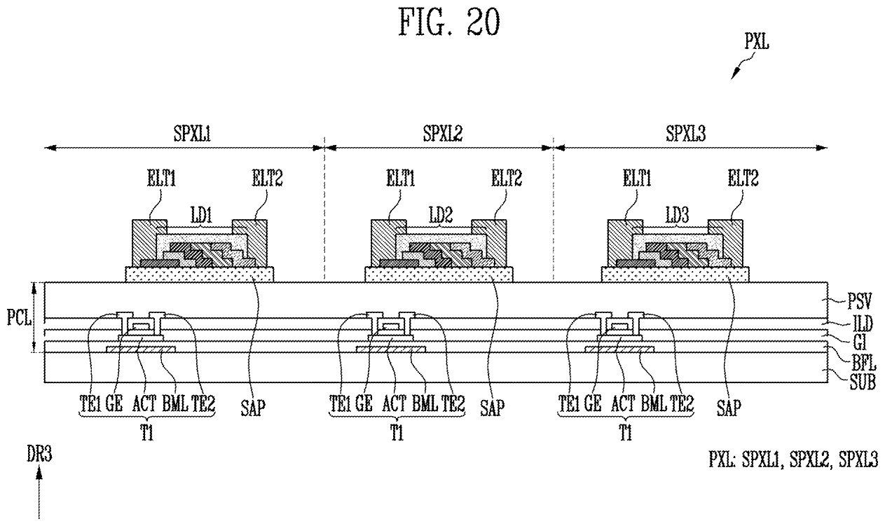

FIG. 20 is a schematic cross-sectional view illustrating the pixel included in the display device of FIG. 1 according to an embodiment. Regarding the embodiment of FIG. 20, differences from the above-described embodiments (for example, the embodiments of FIGS. 17 to 19) will be described in order to avoid redundant description. An embodiment to which the light emitting element LD of FIGS. 3 to 5 is applied to the embodiment of FIG. 20 is shown, but the disclosure is not limited thereto, and the embodiments of FIGS. 7 to 14 may be applied to FIG. 20.

Referring to FIG. 20, a pixel PXL may include sub-pixels SPXL1 to SPXL3. For example, the pixel PXL may include a first sub-pixel SPXL1, a second sub-pixel SPXL2, and third sub-pixels SPXL3.

Each of the sub-pixels SPXL1 to SPXL3 may emit light of a color (e.g., a predetermined or selectable color). According to an embodiment, the sub-pixels SPXL1 to SPXL3 may emit light of different colors. For example, the first sub-pixel SPXL1 may emit light of a first color, the second sub-pixel SPXL2 may emit light of a second color, and the third sub-pixel SPXL3 may emit light of a third color.

In an embodiment, the sub-pixels SPXL1 to SPXL3 may include light emitting elements LD1 to LD3 emitting light of different colors. For example, the first sub-pixel SPXL1 may include a first light emitting element LD1 of the first color, the second sub-pixel SPXL2 may include a second light emitting element LD2 of the second color, and the third sub-pixel SPXL3 may include a third light emitting element LD3 of the third color. For example, the first light emitting element LD1 may be a red light emitting element, the second light emitting element LD2 may be a green light emitting element, and the third light emitting element LD3 may be a blue light emitting element. Even in case that the light conversion layer LCPL of FIGS. 17 to 19 is not provided, the display device including the pixel PXL may display a full-color image.

A display device according to embodiments of the disclosure may include a dedicated substrate SAP (or growth substrate) disposed on a lower panel BP (a lower panel including a transistor T), and a first semiconductor layer SCL1, a light emitting layer EML, a second semiconductor layer SCL2, and an electrode layer ETL sequentially stacked on the dedicated substrate SAP. The first semiconductor layer SCL1, the light emitting layer EML, the second semiconductor layer SCL2, and the electrode layer ETL may constitute or define a light emitting element LD. Instead of arranging or mounting (or bonding) separately manufactured light emitting element LD on the lower panel BP, the light emitting element LD may be disposed in the form of a layer. Accordingly, a process of aligning the light emitting element LD may be omitted, and a manufacturing process of the display device may be simplified. Since there is no problem in that light emitting elements LD are not uniformly aligned, the yield of the display device can be improved.

Effects according to the embodiments are not limited by the above-described contents, and more various other effects are included in the disclosure.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel circuit layer including a transistor;
a growth substrate disposed on the pixel circuit layer;
a light emitting element disposed on the growth substrate; and
an electrode disposed on the light emitting element and electrically connecting the light emitting element and the transistor.

2. The display device of claim 1, wherein the growth substrate is a base layer for epitaxial growth of the light emitting element and is a sapphire substrate.

3. The display device of claim 1, wherein
the light emitting element is an inorganic light emitting element,
the light emitting element includes:
a first semiconductor layer disposed on the growth substrate;
a light emitting layer disposed on the first semiconductor layer;
a second semiconductor layer disposed on the light emitting layer;
an electrode layer disposed on the second semiconductor layer; and
an insulating layer disposed on the electrode layer, covering the light emitting layer and the second semiconductor layer, and partially exposing the electrode layer, and
the electrode electrically connects the electrode layer and the transistor.

4. The display device of claim 3, further comprising:
sub-pixels each including the light emitting element,
wherein the growth substrate is provided in an island shape in each of the sub-pixels.

5. The display device of claim 3, wherein the growth substrate is disposed on an entire area of the pixel circuit layer.

6. The display device of claim 3, wherein
the first semiconductor layer, the light emitting layer, the second semiconductor layer, and the electrode layer are sequentially stacked on an upper surface of the growth substrate in a direction inclined with respect to the upper surface of the growth substrate, and
lower surfaces of the first semiconductor layer, the light emitting layer, the second semiconductor layer, and the electrode layer are positioned on a same plane.

7. The display device of claim 6, wherein each of the first semiconductor layer, the light emitting layer, the second semiconductor layer, and the electrode layer partially contacts the growth substrate.

8. The display device of claim 6, further comprising:
a reinforcing layer disposed between the light emitting element and the growth substrate,
wherein each of the light emitting layer, the second semiconductor layer, and the electrode layer partially contacts the reinforcing layer.

9. The display device of claim 8, wherein the reinforcing layer includes silicon oxide.

10. The display device of claim 8, further comprising:
a reflective layer disposed between the reinforcing layer and the growth substrate.

11. The display device of claim 3, wherein at least one of the first semiconductor layer, the light emitting layer, the second semiconductor layer, and the electrode layer includes a curved surface in a cross-sectional view.

12. The display device of claim 3, wherein
the light emitting layer and the second semiconductor layer are spaced apart from the growth substrate, and
a portion of the electrode layer contacts the growth substrate.

13. The display device of claim 12, further comprising:
a second insulating layer disposed between the electrode layer and side surfaces of the first semiconductor layer and the light emitting layer in a cross-sectional view.

14. The display device of claim 3, wherein
the first semiconductor layer has an inclined surface inclined with respect to an upper surface of the growth substrate, and
each of the light emitting layer, the second semiconductor layer, and the electrode layer has a substantially constant thickness in a direction perpendicular to the inclined surface and is stacked on the inclined surface.

15. The display device of claim 14, further comprising:
a reinforcing layer disposed between the light emitting element and the growth substrate; and
a reflective layer disposed between the reinforcing layer and the growth substrate,
wherein each of the light emitting layer, the second semiconductor layer, and the electrode layer partially contacts the reinforcing layer.

16. The display device of claim 1, further comprising:
a color conversion layer disposed on the light emitting element and converting a wavelength of light emitted from the light emitting element.

17. A method for manufacturing a display device comprising:
forming a growth substrate on a pixel circuit layer including a transistor;
sequentially forming a first semiconductor layer, a light emitting layer, and a second semiconductor layer on the growth substrate;
forming an electrode layer on the second semiconductor layer;
forming an insulating layer covering the light emitting layer and the second semiconductor layer and partially exposing the electrode layer; and
forming an electrode electrically connecting the electrode layer and the transistor.

18. The method of claim 17, wherein
the first semiconductor layer, the light emitting layer, and the second semiconductor layer are formed through an epitaxial growth technique, and
the growth substrate is a sapphire substrate.

19. The method of claim 17, wherein
the first semiconductor layer, the light emitting layer, and the second semiconductor layer are formed through a lateral growth technique,
the first semiconductor layer has an inclined surface inclined with respect to an upper surface of the growth substrate, and
each of the light emitting layer, the second semiconductor layer, and the electrode layer has a thickness in a direction perpendicular to the inclined surface.

20. The method of claim 19, further comprising:
anisotropically etching the first semiconductor layer, the second semiconductor layer, and the electrode layer using a mask before the forming of the insulating layer.
